(19) United States
(12) Patent Application Publication
(10) Pub. No.: US 2016/0163603 A1
(43) Pub. Date: Jun. 9, 2016

(54) PFET GATE STACK MATERIALS HAVING IMPROVED THRESHOLD VOLTAGE, MOBILITY AND NBTI PERFORMANCE

(71) Applicant: International Business Machines Corporation, Armonk, NY (US)

(72) Inventors: Ruqiang Bao, Wappingers Falls, NY (US); Siddarth Krishnan, Fishkill, NY (US); Unoh Kwon, Fishkill, NY (US); Keith Kwong Hon Wong, Wappingers Falls, NY (US)

(21) Appl. No.: 14/562,991

(22) Filed: Dec. 8, 2014

(51) Int. Cl. H01L 21/8238; H01L 29/49; H01L 21/28

(52) U.S. Cl. CPC H01L 21/823842; H01L 21/28088; H01L 29/4966

(57) ABSTRACT

A method of forming a transistor device includes forming an interfacial layer and a dielectric layer over a substrate; and forming a p-type field effect transistor (PFET) workfunction metal layer over the dielectric layer, the workfunction metal layer comprising a lower titanium nitride (TiN) first layer and a second layer including one of titanium-aluminum-carbide (TiAlC) and tantalum-aluminum-carbide (TaAlC) formed on the lower TiN first layer.

### BACKGROUND

The present invention relates generally to semiconductor device manufacturing and, more particularly, to PFET gate stack materials having improved threshold voltage, mobility and negative bias temperature instability (NBTI) performance.

Field effect transistors (FETs) are widely used in the electronics industry for switching, amplification, filtering, and other tasks related to both analog and digital electrical signals. Most common among these are metal-oxide-semiconductor field-effect transistors (MOSFET or MOS), in which a gate structure is energized to create an electric field in an underlying channel region of a semiconductor body, by which electrons are allowed to travel through the channel between a source region and a drain region of the semiconductor body. Complementary MOS (CMOS) devices have become widely used in the semiconductor industry, wherein both n-type and p-type (NMOS and PMOS) transistors are used to fabricate logic and other circuitry.

The source and drain regions of an FET are typically formed by adding dopants to targeted regions of a semiconductor body on either side of the channel. A gate structure is formed above the channel, which includes a gate dielectric located over the channel and a gate conductor above the gate dielectric. The gate dielectric is an insulator material, which prevents large leakage currents from flowing into the channel when a voltage is applied to the gate conductor, while allowing the applied gate voltage to set up a transverse electric field in the channel region in a controllable manner. Conventional MOS transistors typically include a gate dielectric formed by depositing or by growing silicon dioxide (SiO₂) or silicon oxynitride (SiON) over a silicon wafer surface, with doped polysilicon formed over the SiO₂ to act as the gate conductor. The gate conductor serves as an interconnect structure, as well as the controller of gate threshold voltage for MOSFETs.

Continuing trends in semiconductor device manufacturing include reduction in electrical device feature sizes (i.e., scaling), as well as improvements in device performance in terms of device switching speed and power consumption. MOS transistor performance may be improved by reducing the distance between the source and the drain regions under the gate conductor of the device, known as the gate or channel length, and by reducing the thickness of the layer of gate dielectric that is formed over the semiconductor surface to increase the gate capacitance. However, there are electrical and physical limitations on the extent to which the thickness of SiO₂ gate dielectrics can be reduced. For example, thin SiO₂ gate dielectrics are prone to gate tunneling leakage currents resulting from direct tunneling of electrons through the thin gate dielectric.

Scaling of the gate dielectric is a challenge in improving performance of advanced field effect transistors. In a field effect transistor employing a silicon oxide based gate dielectric, the leakage current through the gate dielectric increases exponentially with the decrease in the thickness of the gate dielectric. Such devices typically become too leaky to provide high performance at or below a thickness of about 1.1 nm for the silicon oxide gate dielectric.

Accordingly, recent MOS and CMOS transistor scaling efforts have focused on high-κ dielectric materials having dielectric constants greater than that of SiO₂ (e.g., greater than about 3.9). High-κ dielectric materials can be formed in a thicker layer than scaled SiO₂, and yet still produce equivalent field effect performance. The relative electrical performance of such high-κ dielectric materials is often expressed in terms equivalent oxide thickness (EOT), since the high-κ material layer may be physically thicker, while still providing the electrical equivalent or thinner oxide thickness than scaled SiO₂. Because the dielectric constant “κ” is higher than silicon dioxide, a thicker high-κ dielectric layer can be employed to mitigate tunneling leakage currents, while still achieving the equivalent or better electrical performance of a thinner layer of thermally grown SiO₂.

### SUMMARY

In one aspect, a method of forming a transistor device includes forming an interfacial layer and a dielectric layer over a substrate; and forming a p-type field effect transistor (PFET) workfunction metal layer over the dielectric layer, the workfunction metal layer including a lower titanium nitride (TiN) first layer and a second layer comprising one of titanium-aluminum-carbide (TiAlC) and tantalum-aluminum-carbide (TaAlC) formed on the lower TiN first layer.

In another aspect, a method of forming a complementary metal oxide semiconductor (CMOS) device, the method includes forming an interfacial layer and a dielectric layer over a substrate; and forming a p-type field effect transistor (PFET) workfunction metal layer over the dielectric layer in a PFET region, and forming an n-type field effect transistor (NFET) workfunction metal layer over the dielectric layer in an NFET region; wherein the PFET workfunction metal layer includes a lower titanium nitride (TiN) first layer and a second layer including one of a titanium-aluminum-carbide (TiAlC) layer and a tantalum-aluminum-carbide (TaAlC) layer formed on the lower TiN first layer.

In still another aspect, a transistor device includes an interfacial layer and a dielectric layer formed over a portion of a substrate; and a p-type field effect transistor (PFET) workfunction metal layer formed over the dielectric layer, the workfunction metal layer including a lower titanium nitride (TiN) first layer and a second layer including one of titanium-aluminum-carbide (TiAlC) and tantalum-aluminum-carbide (TaAlC) formed on the lower TiN first layer.

### BRIEF DESCRIPTION OF THE DRAWINGS

Referring to the exemplary drawings wherein like elements are numbered alike in the several Figures:

FIGS. 1 through 7 are cross sectional views of an exemplary embodiment of a method of forming a high-κ PFET gate stack for CMOS devices, in which:

FIG. 1 illustrates the formation of a PFET workfunction metal stack over NFET and PFET regions of a device;

FIG. 2 illustrates patterning of the device of FIG. 1 prior to removal of the PFET workfunction metal stack in the NFET region;

FIG. 3 illustrates the removal of the PFET workfunction metal stack in the NFET region;

FIG. 4 illustrates the removal of the masking layer in FIG. 3;

FIG. 5 illustrates the formation of an NFET workfunction metal stack over the NFET and PFET regions of the device;

FIG. 6 illustrates remaining gate metal fill over the NFET and PFET regions of the device;

FIG. 7 illustrates planarization of the NFET and PFET gate stacks;

FIG. 8 is a flow diagram summarizing the method of forming a high-κ PFET gate stack for CMOS devices illustrated in FIGS. 1-7;

FIGS. 9 through 15 are cross sectional views of another exemplary embodiment of a method of forming a high-κ PFET gate stack for CMOS devices, in which:

FIG. 9 illustrates the formation of an NFET workfunction metal stack over NFET and PFET regions of a device;

FIG. 10 illustrates patterning of the device of FIG. 9 prior to removal of the NFET workfunction metal stack in the PFET region;

FIG. 11 illustrates the removal of the NFET workfunction metal stack in the PFET region;

FIG. 12 illustrates the removal of the masking layer in FIG. 3;

FIG. 13 illustrates the formation of a PFET workfunction metal stack over the NFET and PFET regions of the device;

FIG. 14 illustrates remaining gate metal fill over the NFET and PFET regions of the device;

FIG. 15 illustrates planarization of the NFET and PFET gate stacks; and

FIG. 16 is a flow diagram summarizing the method of forming a high-κ PFET gate stack for CMOS devices illustrated in FIGS. 9-15.

### DETAILED DESCRIPTION

For a high performance CMOS device, the inversion capacitance-based oxide equivalent thickness, also referred to simply as “inversion thickness” (Tᵢₙᵥ), of gate dielectrics should be scaled down below about 11 angstroms (Å) for future technologies. Tᵢₙᵥ measures the incremental inversion charge density per gate voltage swing. Due to inversion layer quantization and polysilicon gate depletion effects, Tᵢₙᵥ is thicker than EOT. As such, scaling of EOT also results in scaling of Tᵢₙᵥ.

A replacement gate process architecture avoids the problems of workfunction material stability seen in a gate first architecture. Here, a dummy gate structure is used to self-align the source and drain implant and anneals, followed by stripping out the dummy gate materials and replacing them with the high-κ and metal gate materials. Although this process is more complex than a gate first technique, advantages of a replacement gate flow include the use of separate PFET and NFET metals for workfunction optimization. In addition, the two metals are not exposed to high temperatures, simplifying material selection. Further, the polysilicon gate removal can actually be used to enhance strain techniques, thereby increasing drive currents.

Currently, there are limited options/materials available in replacement metal gate processing that can lower PFET threshold voltage (Vt), enhance mobility, and also improve NBTI for high performance FinFET CMOS devices. Traditionally, titanium nitride (TiN) has been a good selection for a workfunction metal for PFET devices. However, for 14 nm technology and beyond, due to the three dimension structure in FinFET devices, atomic layer deposition (ALD) has become a “must technique” for depositing highly uniform and conformal workfunction metals to reduce Vt variation and also to have good Vt control. Due to the intrinsic characteristics of ALD processes, accomplishing a workfunction change (like a film composition change) via this process is quite difficult. Thus, other methods are needed to adjust the PFET workfunction.

Accordingly, disclosed herein is a novel PFET workfunction stack for CMOS device processing. In exemplary embodiments, a tri-layer stack includes a thin, bottom layer of TiN, followed by a thin layer of titanium-aluminum-carbide (TiAlC) on the bottom TiN layer, and a thicker layer of TiN on the TiAlC layer to set up the PFET workfunction. Tantalum-aluminum-carbide (TaAlC) may also be used in lieu of or in addition to TiAlC. The use of this PFET workfunction stack has yielded the following observed improvements with respect to conventional stacks: a reduced threshold voltage (pVt) by approximately 30-40 millivolts (mV) at similar inversion thicknesses for devices not additionally treated and by approximately 40-50 mV for additionally treated devices; an improved NBTI by approximately 50 mV at similar at similar inversion thicknesses for devices not additionally treated and by about 60 mV for additionally treated devices, and an improved maximum mobility by 10 units at similar inversion thicknesses for devices not additionally treated and by 15 units for additionally treated devices.

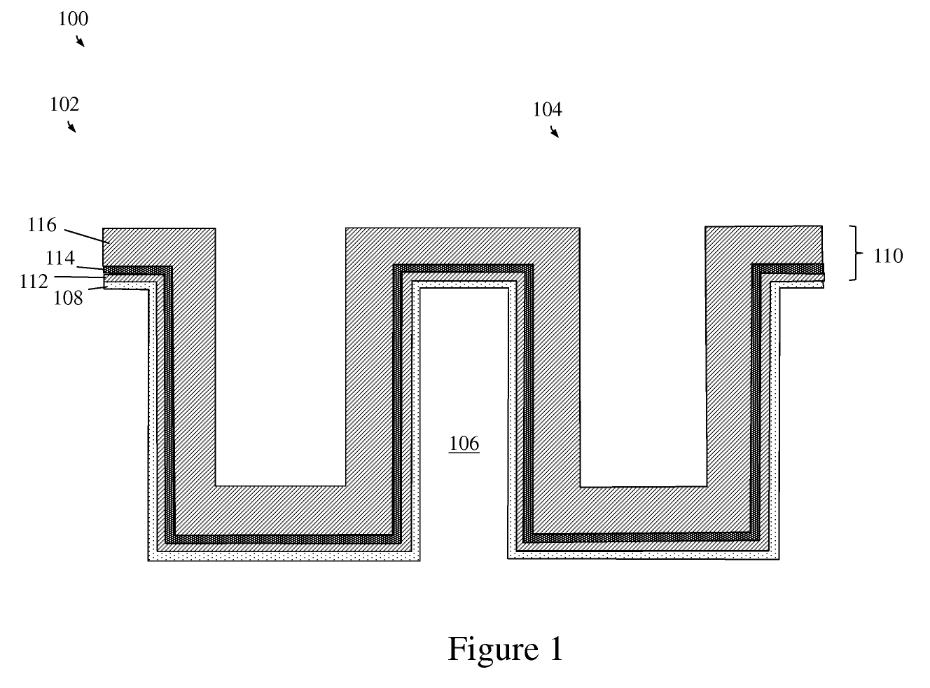

Referring initially to FIGS. 1 through 7, there is shown a series of cross sectional views of an exemplary embodiment of a method of forming a high-κ PFET gate stack for CMOS devices. In this first embodiment, the PFET workfunction metal stack is formed prior to the NFET workfunction metal stack. It will also be appreciated that the exemplary embodiments are applicable to, for example, replacement gate planar FET devices as well as replacement gate FinFET devices.

As shown in FIG. 1, a CMOS device 100 includes an NFET region 102 and a PFET region 104 defined in a semiconductor substrate 106. The semiconductor substrate 106 includes a semiconductor material, which may be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Where the semiconductor material of the semiconductor substrate 106 is a single crystalline silicon-containing semiconductor material, the single crystalline silicon-containing semiconductor material may be selected from single crystalline silicon, a single crystalline silicon carbon alloy, a single crystalline silicon germanium alloy, and a single crystalline silicon germanium carbon alloy.

In general, the semiconductor material of the semiconductor substrate 106 may be appropriately doped either with p-type dopant atoms or with n-type dopant atoms. The dopant concentration of the semiconductor substrate 102 may range from approximately 1.0×10¹⁵ atoms/cm³ to 1.0×10¹⁹ atoms/cm³, and more specifically from approximately 1.0×10¹⁶ atoms/cm³ to 3.0×10¹⁸ atoms/cm³, although lesser and greater dopant concentrations are contemplated herein also. In addition, the semiconductor substrate 102 may be a bulk substrate, a semiconductor-on-insulator or silicon-on-insulator (SOI) substrate, or a hybrid substrate, and may have one or more shallow trench isolation structures (not shown) formed therein that include a dielectric material such as silicon oxide or silicon nitride, and are formed by methods well known in the art.

For an example of replacement gate FET technology, FIG. 1 may represent dummy gate structures having been removed, such as through one or more etch processes. Prior to workfunction metal formation, and interfacial layer/high-κ dielectric layer 108 is formed on the exposed semiconductor surface of the substrate 106. In an exemplary embodiment, the interfacial layer (IL) portion of layer 108 may be formed by a chemical oxide process such as by a wet chemical oxidation that includes treating the cleaned semiconductor surface 106 (e.g., by hydrofluoric acid) with a mixture of ammonium hydroxide, hydrogen peroxide and water (in a 1:1:5 ratio) at 65° C. Alternatively, the chemical oxide layer can also be formed by treating the HF-last semiconductor surface in ozonated aqueous solutions, with the ozone concentration usually varying from, but not limited to, 2 parts per million (ppm) to 40 ppm. However, it will be appreciated that the IL portion of layer 108 may be formed by other processes known in the art such as, for example, by atomic layer deposition (ALD) of SiO₂ or by rapid thermal anneal (RTA) in an O₂ or NH₃ ambient environment. The formation of the IL portion allows for nucleation of a high-κ dielectric layer formed thereon, which includes a dielectric metal oxide having a dielectric constant that is greater than the dielectric constant (7.5) of silicon nitride.

The high-κ dielectric portion of layer 108 may be formed by methods well known in the art including, for example, chemical vapor deposition (CVD), ALD, molecular beam deposition (MBD), pulsed laser deposition (PLD), liquid source misted chemical deposition (LSMCD), etc. In an exemplary embodiment, the dielectric metal oxide of the high-κ dielectric portion of layer 108 includes a metal and oxygen, and optionally nitrogen and/or silicon. Specific examples of high-κ dielectric materials include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from 0.5 to 3 and each value of y is independently from 0 to 2. The thickness of the high-κ dielectric portion of layer 108 may be from about 1 nm to about 10 nm, and more specifically from about 1.5 nm to about 3 nm. Following the formation of the high-κ dielectric portion of layer 108, an optional anneal may be performed to densify the high-κ material.

As further shown in FIG. 1, a PFET workfunction stack 110 is formed over layer 108, such as by ALD. The stack 110 includes a thin, lower TiN layer 112, formed at a thickness of approximately 2-8 angstroms (Å), followed by a thin TiAlC (or TaAlC) layer 114, formed at a thickness of approximately 12 Å or less. The lower TiN layer 112 acts a barrier between the thin TiAlC layer 114 and the interfacial layer/high-κ dielectric layer 108, avoiding Tᵢₙᵥ penalties. In addition, an upper TiN layer 116 may also be formed for improving PFET resistance and/or patterning (thicker than that of the lower TiN layer 112) or present the effect of NFET workfunction metals (or gate fill metals) on the PFET workfunction stack, such as at a thickness of about 15-100 Å. This upper TiN layer may also be omitted in the absence of the aforementioned concerns.

In one embodiment, the TiN/TiAlC/TiN (or TiN/TaAlC/TiN) stack 112/114/116 may be deposited in-situ, i.e., without an air break between these layers, in order to lower the gate resistance by reducing the interface effect between these layers. Other schemes like TiN/TiAlC (in-situ)/air break/TiN, or TiN/air break/TiAlC/TiN are also contemplated herein.

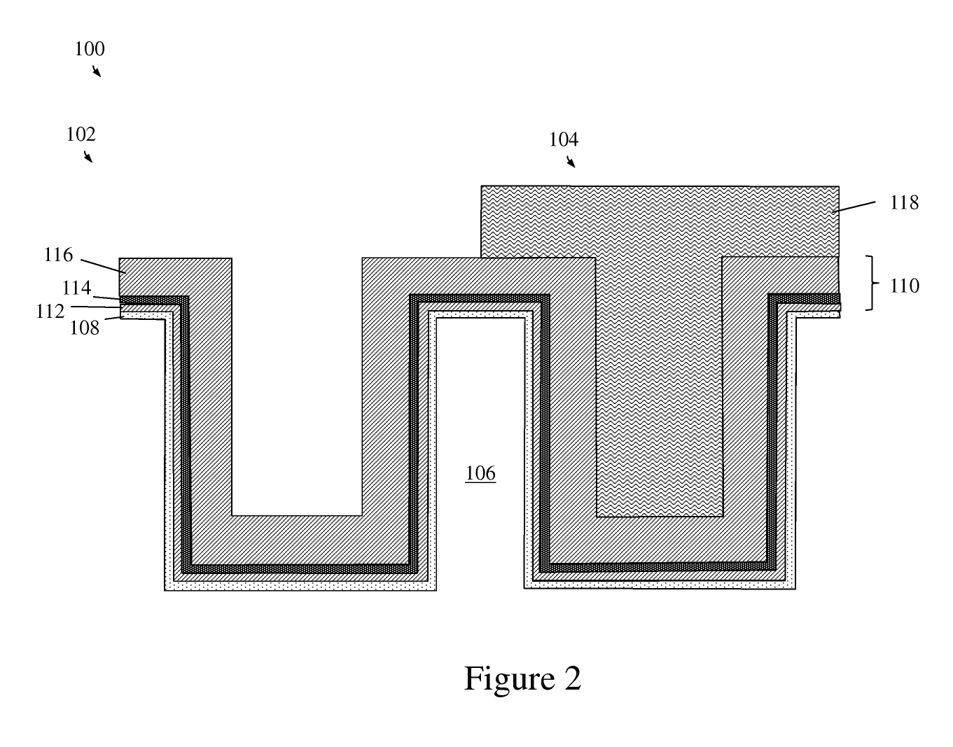

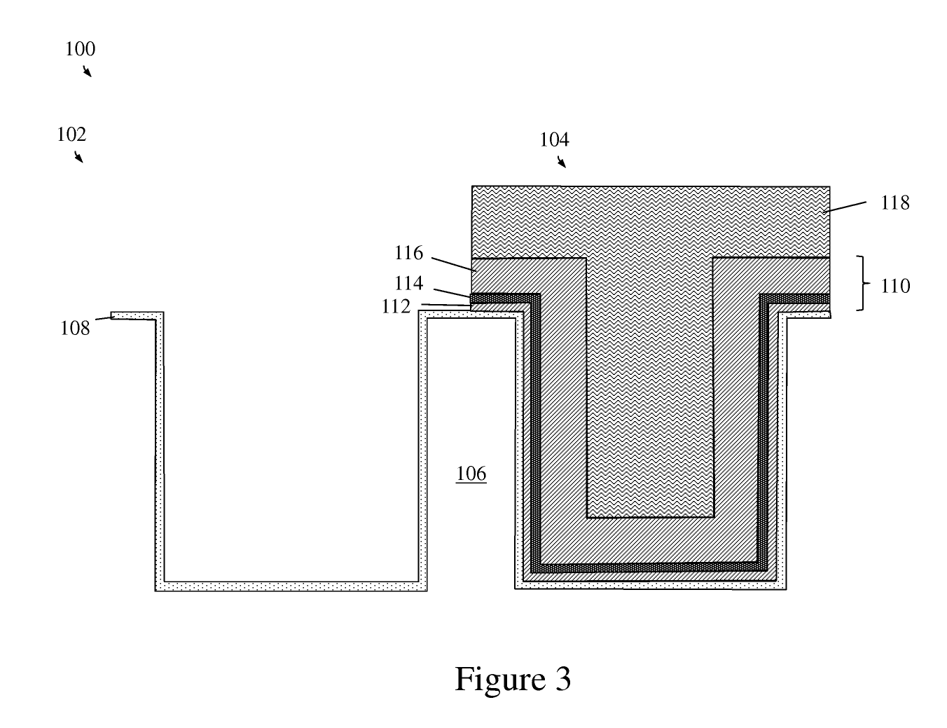

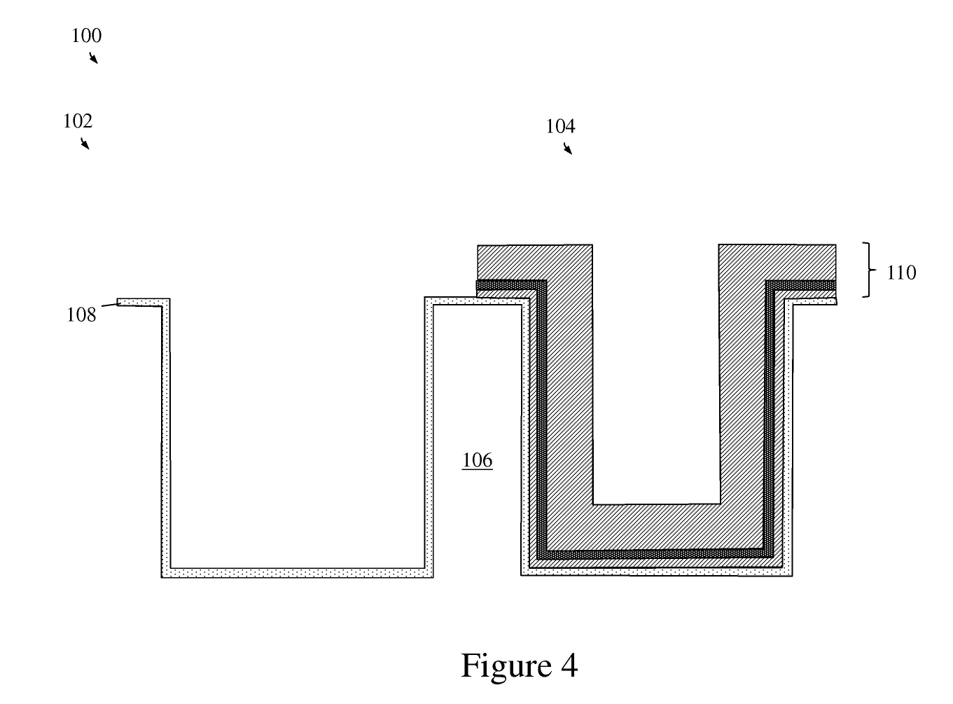

FIG. 2 illustrates patterning of a mask material 118 (such as a photoresist layer or hardmask) prior to removal of the PFET workfunction metal stack 110 in the NFET region 102. Then, as shown in FIG. 3, the unmasked portions of the PFET workfunction metal stack 110 in the NFET region 102 are removed, such as by reactive ion etching (RIE) and wets like standard SC1 or peroxide (H₂O₂), for example, stopping on the interfacial layer/high-κ dielectric layer 108. The mask material 118 may then be removed, as shown in FIG. 4.

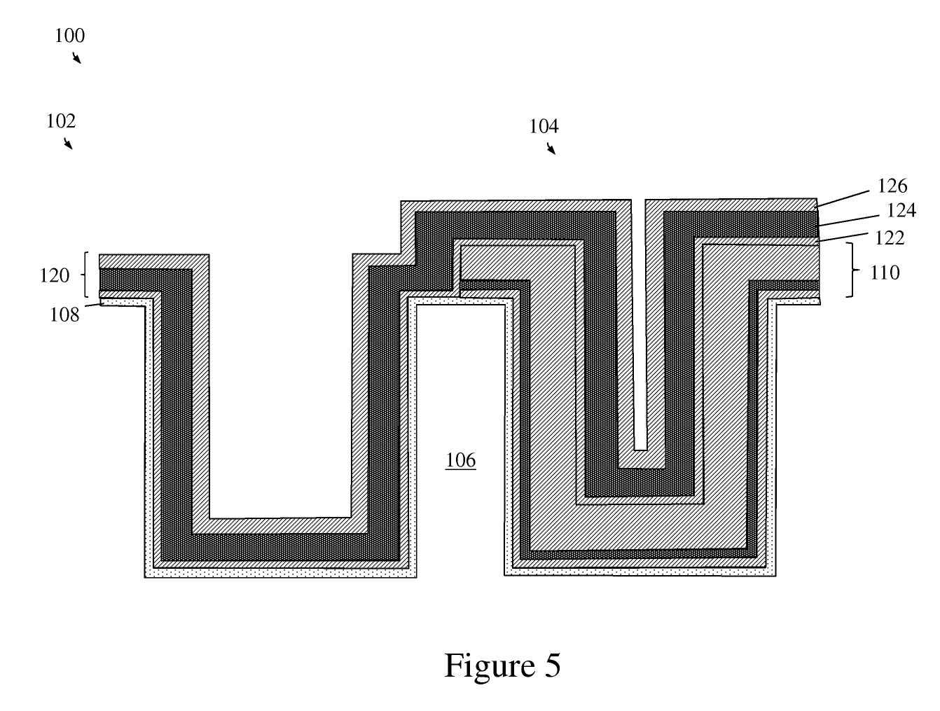

Once the patterning of the novel PFET workfunction metal stack 110 is completed, the process continues with reference to FIG. 5, which illustrates the deposition of an NFET workfunction metal stack 120 over the device 100, such as by ALD. The stack 120 includes a TiN layer 122 (which may be formed at a greater thickness with respect to the lower TiN layer 112 of the PFET workfunction metal stack 110), followed by a TiAlC layer 124 (which may be formed at a greater thickness with respect to the TiAlC layer 114 of the PFET workfunction metal stack 110). In addition, a wetting TiN layer 126 may also be formed for improving adherence by a subsequent gate metal fill. Here, the NFET metal stack can be another metal stack which can serve as a gate metal to tune NFET threshold voltage.

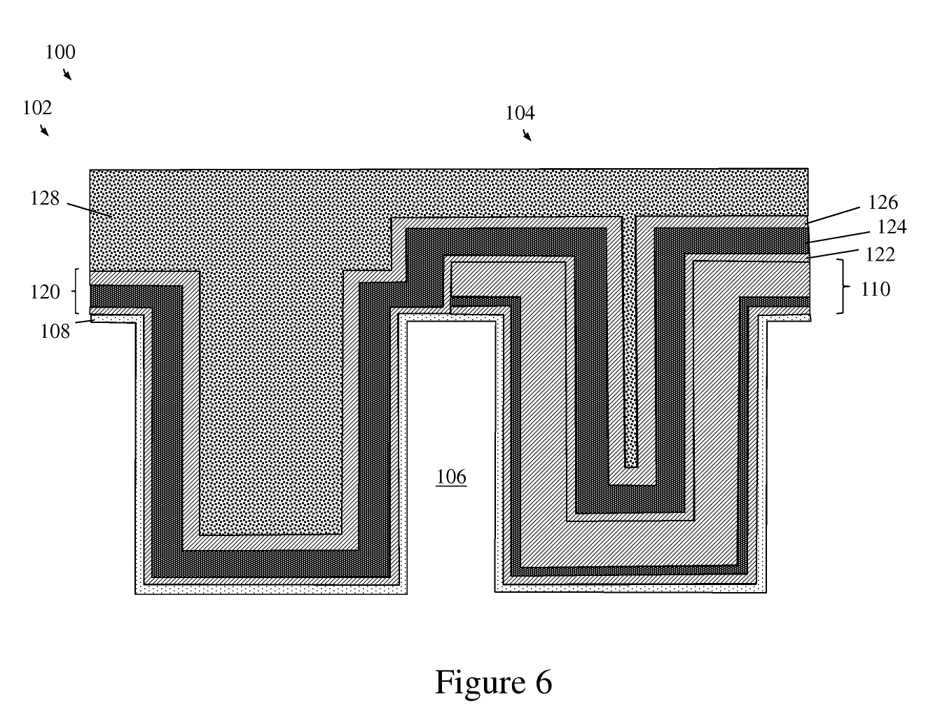

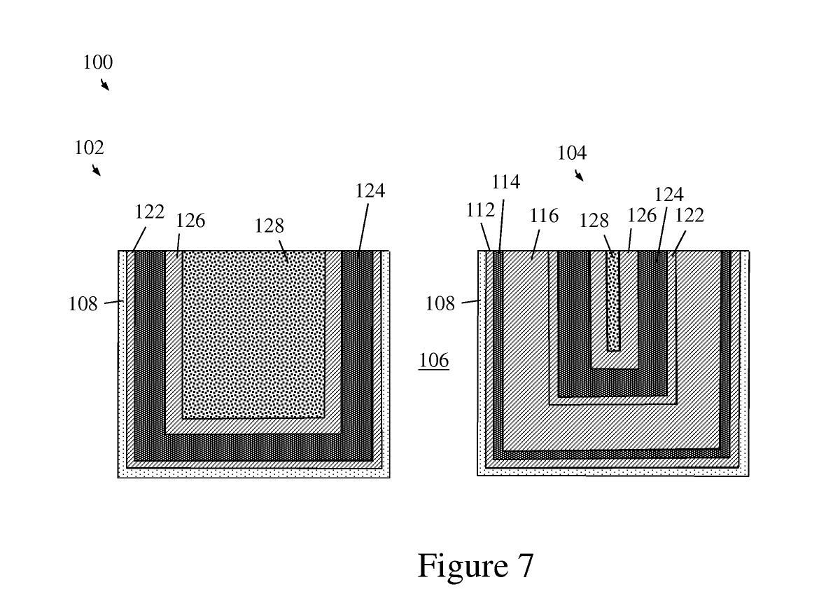

It will be noted that for the PFET first deposition embodiment, the subsequently deposited NFET workfunction metal stack 120 may remain atop the PFET workfunction metal stack 110 prior to completing the gate metal fill process. As shown in FIG. 6, a gate metal fill material 128 such as tungsten (W) for example, is used to fill the remaining portions of the openings in the NFET region 102 and PFET region 104. The layers are then planarized, such as by chemical mechanical polishing (CMP) as shown in FIG. 7 to form the NFET and PFET gate stacks, after which processing may continue as known in the art.

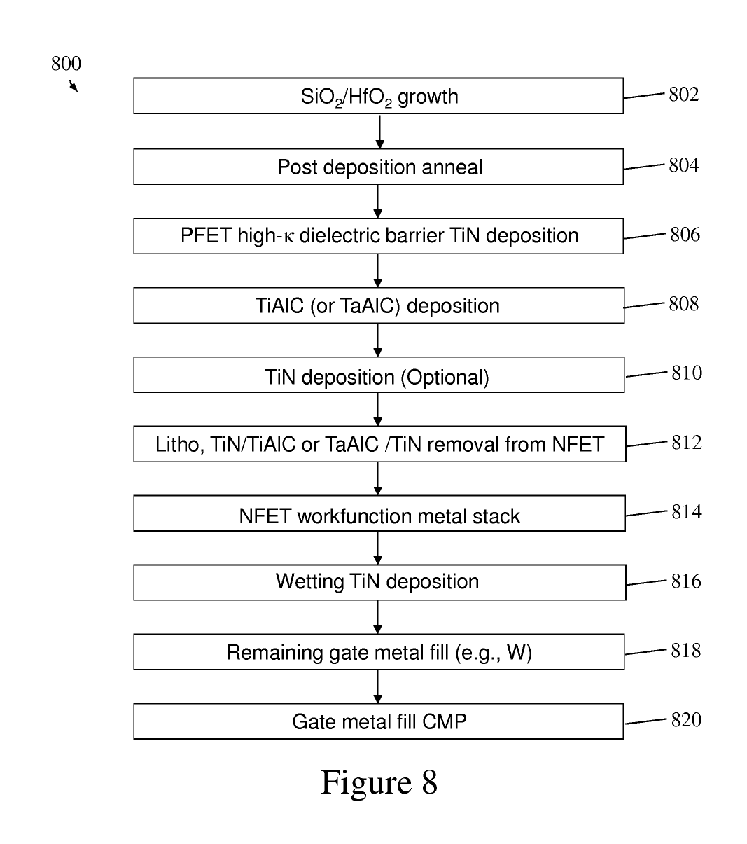

FIG. 8 is a flow diagram 800 that summarizes the PFET first deposition embodiment described above. The PFET first process flow 800 begins at block 802 with the formation of an interfacial layer and high-κ layer (e.g., SiO₂/HfO₂) for example following the removal of dummy gate material. After an optional post deposition anneal in block 804, the process flow 800 proceeds to block 806 for deposition of the thin, barrier TiN layer on the interfacial layer/high-κ layer. This is followed by deposition of the thin TiAlC (or TaAlC) layer as depicted in block 808, and then a TiN layer may also be formed over the TiAlC PFET workfunction metal layer for gate resistance or as a wetting layer for metal fill as shown in block 810. Again, this top TiN can also be skipped in the absence of such concerns. The flow operations through block 810 may also be visualized with reference once again to FIG. 1.

In block 812, the device is lithographically patterned as known in the art to remove the TiN/TiAlC PFET workfunction metal layers (and optional TiN layer) from NFET portions of the device (which is also depicted in FIGS. 2-4). Thereafter, with the PFET workfunction metal in place in the PFET region, the NFET workfunction metals are deposited as shown in block 814. Suitable NFET workfunction metals may include for example, TiN and TiAlC. Following the deposition of the NFET workfunction metals, a wetting TiN deposition may be used as shown in block 816 (and also FIG. 5) for adhesion of the subsequent gate metal fill in block 818 to the workfunction metal (see also FIG. 6). The stacks are then planarized in block 820 (and also FIG. 7).

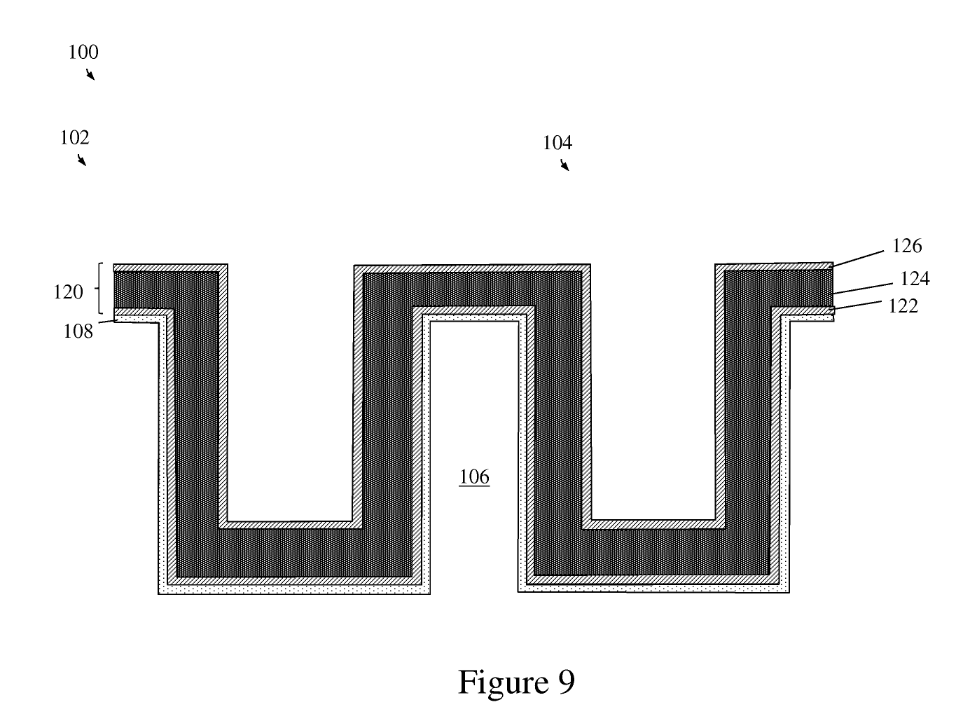

In the context of CMOS device processing, it is contemplated that the NFET workfunction metals may be formed first, prior to the PFET workfunction metals. Referring generally now to FIGS. 9 through 15, there is shown a series of cross sectional views of another exemplary embodiment of a method of forming a high-κ PFET gate stack for CMOS devices. In this second embodiment, the NFET workfunction metal stack is formed prior to the PFET workfunction metal stack. For ease of illustration, similar reference numbers are used to represent similar features among the embodiments.

As shown in FIG. 9, an NFET workfunction metal stack 120 is formed over layer 108, such as by ALD. Similar to the first embodiment, the NFET workfunction metal stack 120 includes a TiN layer 122 (which may be formed at a greater thickness with respect to a subsequently formed lower TiN layer of a PFET workfunction metal stack), followed by a TiAlC layer 124 (which may be formed at a greater thickness with respect to a TiAlC layer of the subsequently formed PFET workfunction metal stack). The NFET workfunction metal stack 120 may also include TiN layer 126 for patterning purposes.

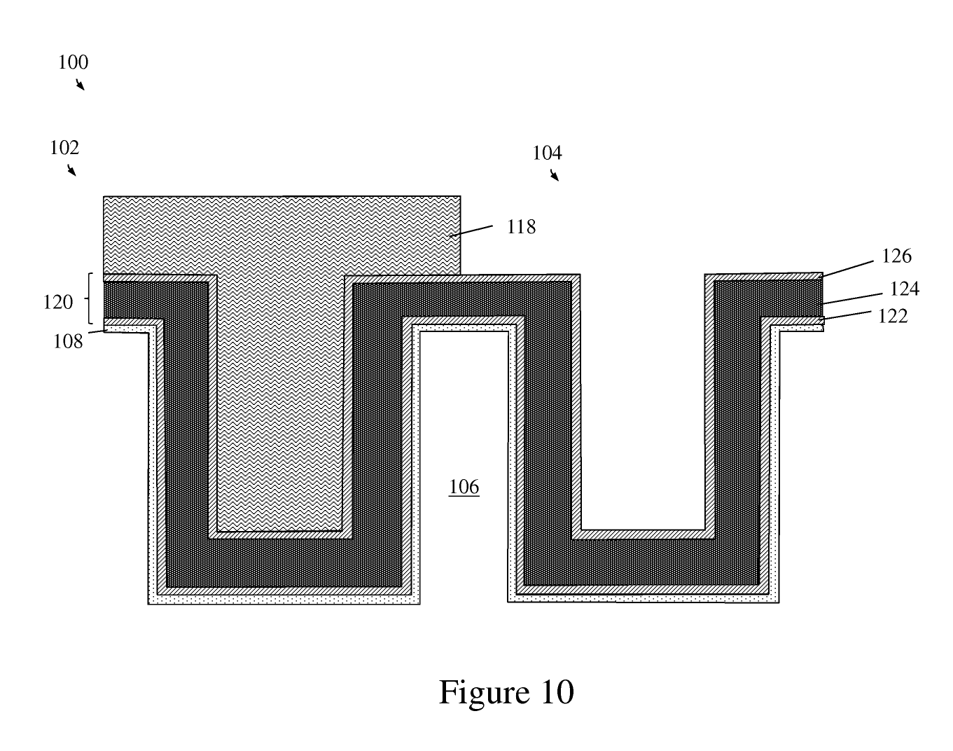

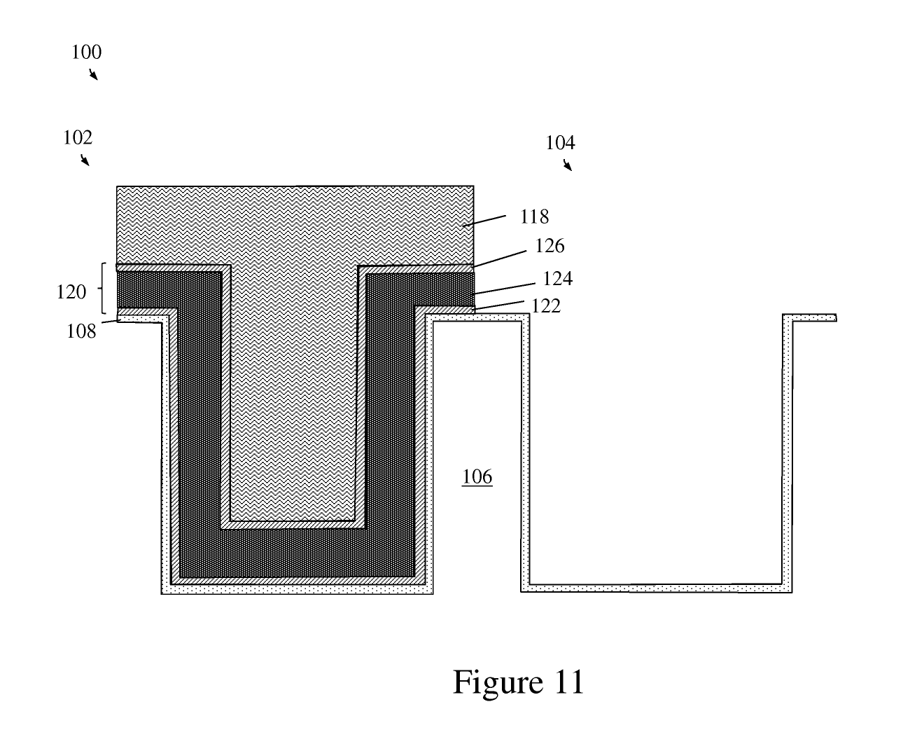

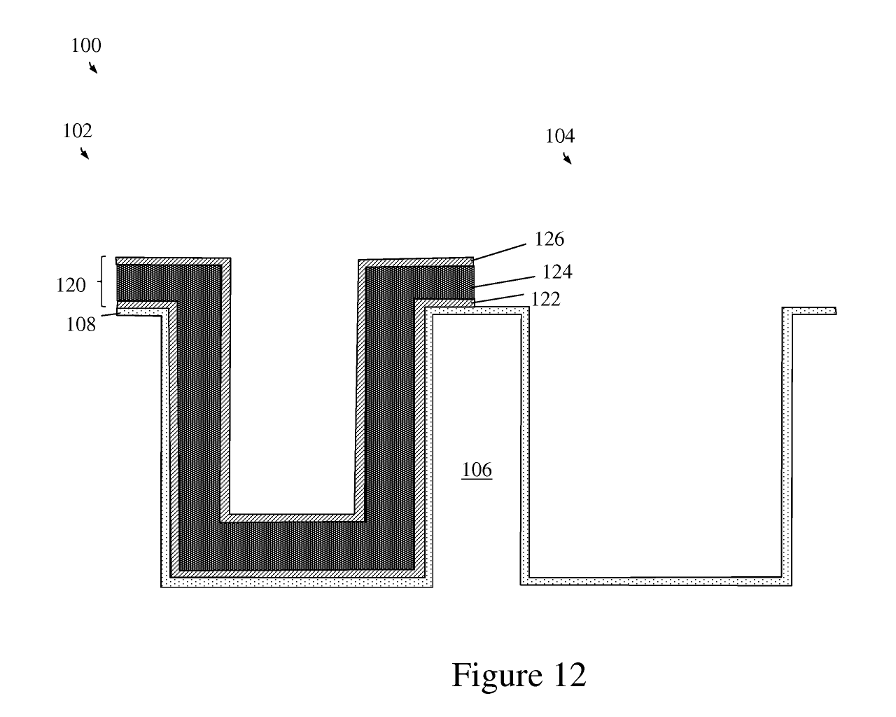

FIG. 10 illustrates patterning of a mask material 118 (such as a photoresist layer or hardmask) prior to removal of the NFET workfunction metal stack 120 in the PFET region 104. Then, as shown in FIG. 11, the unmasked portions of the NFET workfunction metal stack 120 in the PFET region 104 are removed, such as by RIE or wets like standard SC1 or peroxide (H₂O₂), for example, stopping on the interfacial layer/high-κ dielectric layer 108. The mask material 118 may then be removed, as shown in FIG. 12.

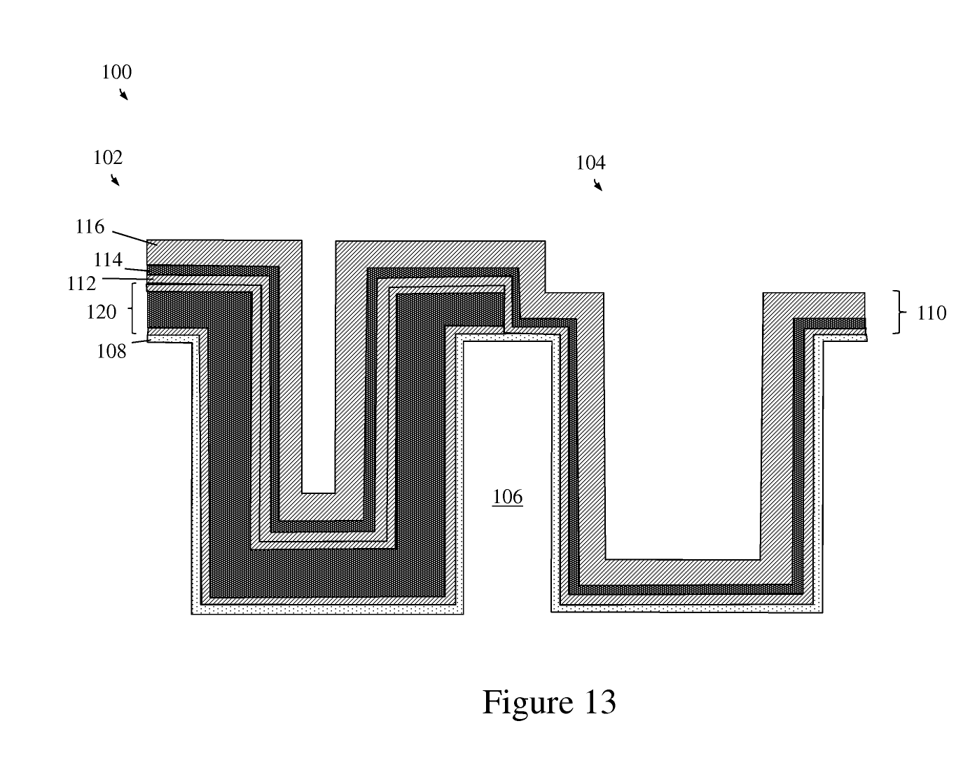

Once the patterning of the NFET workfunction metal stack 120, the process continues with reference to FIG. 13, which illustrates the deposition of the novel PFET workfunction metal stack 110 over the device 100, such as by ALD. Again, the stack 110 includes a thin, lower TiN layer 112, formed at a thickness of about 2-8 Å, followed by a thin TiAlC (or TaAlC) layer 114, formed at a thickness of about 12 Å or less. In addition, a wetting TiN layer 116 may also be formed at a thickness of about 15-100 Å for improving adherence by a subsequent gate metal fill.

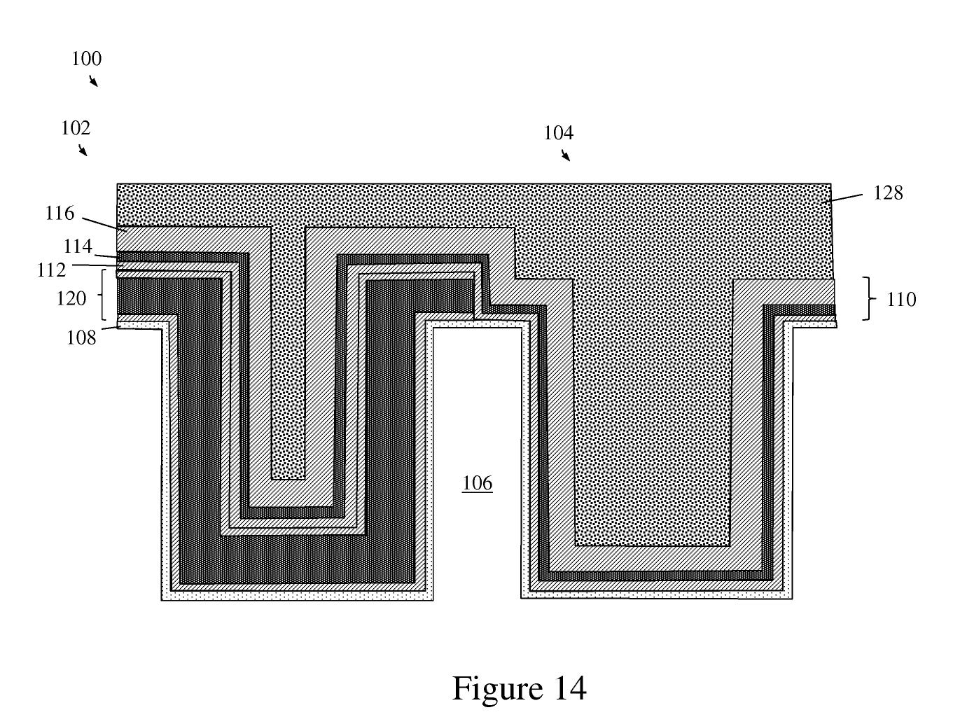

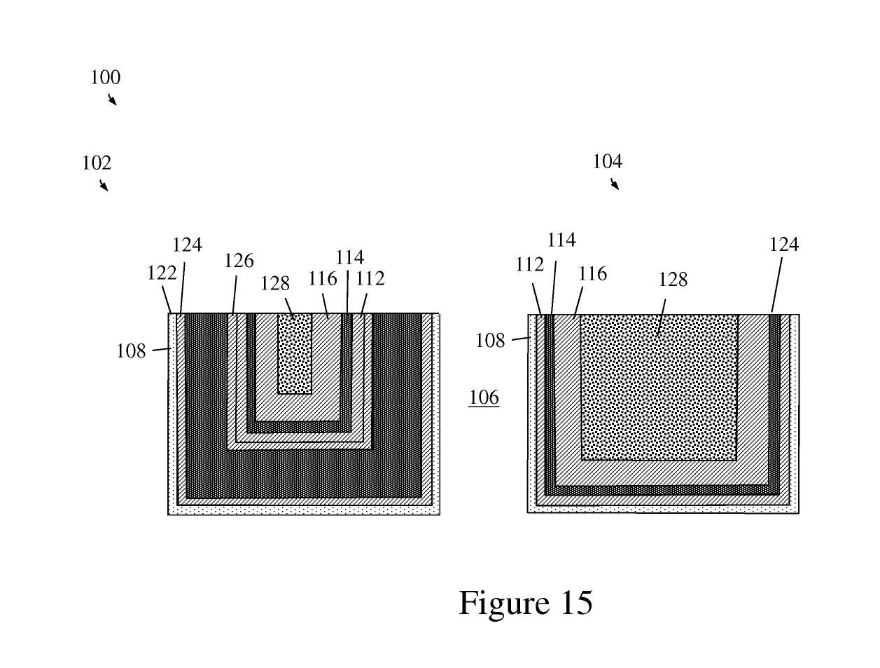

Here, it will be noted that for the NFET first deposition embodiment, the subsequently deposited PFET workfunction metal stack 110 may remain atop the NFET workfunction metal stack 120 prior to completing the gate metal fill process. As shown in FIG. 14, a metal fill material 128 such as tungsten for example, is used to fill the remaining portions of the openings in the NFET region 102 and PFET region 104. The layers are then planarized, such as by chemical mechanical polishing (CMP) as shown in FIG. 15 to form the NFET and PFET gate stacks, after which processing may continue as known in the art.

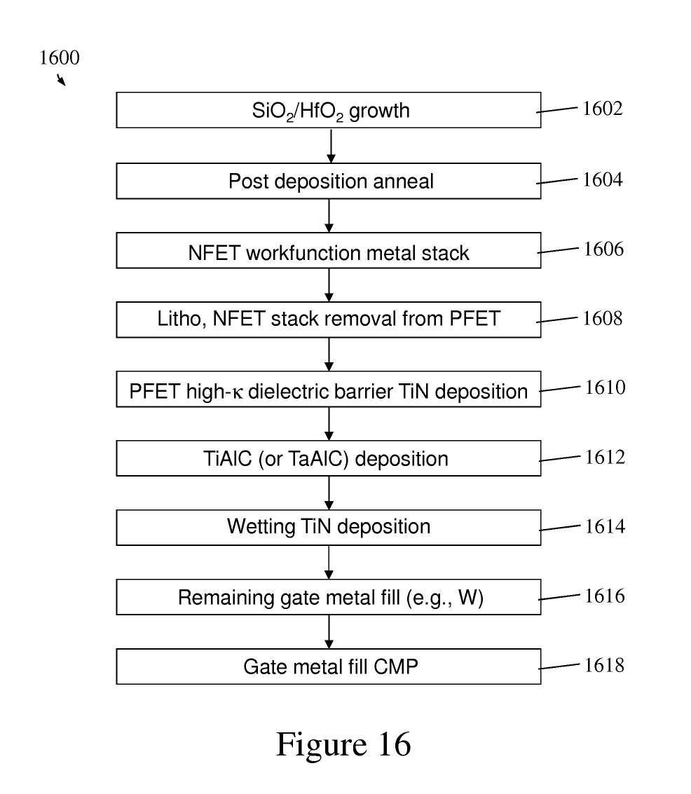

FIG. 16 is a flow diagram 1600 that summarizes the NFET first deposition embodiment described above. The NFET first process flow 1600 begins at block 1602 with the formation of an interfacial layer and high-κ layer (e.g., SiO₂/HfO₂) for example following the removal of dummy gate material. After an optional post deposition anneal in block 1604, the process flow 1600 proceeds to block 1606 for deposition of the NFET workfunction metals and an optional TiN cap layer. The flow operations through block 1606 may also be visualized with reference once again to FIG. 9.

In block 1608, the device is lithographically patterned as known in the art to remove the NFET workfunction metal layers (and optional TiN layer) from PFET portions of the device (which is also depicted in FIGS. 10-12). Thereafter, with the NFET workfunction metal in place in the NFET region, the PFET workfunction metals as described above (i.e., thin barrier TiN and thin TiAlC (or TaAlC)) are deposited as shown in blocks 1610 and 1612, respectively. Following the deposition of the PFET workfunction metals, a wetting TiN deposition may be used as shown in block 1614 (and also FIG. 13) for adhesion of the subsequent gate metal fill in block 1616 to the workfunction metal (see also FIG. 14). The stacks are then planarized in block 1618 (and also FIG. 15).

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method of forming a transistor device, the method comprising:
forming an interfacial layer and a dielectric layer over a substrate; and
forming a p-type field effect transistor (PFET) workfunction metal layer over the dielectric layer, the workfunction metal layer comprising a lower titanium nitride (TiN) first layer and a second layer comprising one of titanium-aluminum-carbide (TiAlC) and tantalum-aluminum-carbide (TaAlC) formed on the lower TiN first layer.

2. The method of claim 1, wherein the lower TiN first layer is formed at thickness of about 2-8 angstroms (Å).

3. The method of claim 1, wherein the second layer is formed at thickness of about 12 Å or less.

4. The method of claim 1, further comprising forming an upper TiN third layer on the second layer, the upper TiN third layer being thicker than the lower TiN first layer.

5. The method of claim 4, wherein the upper TiN third layer is formed at a thickness of about 15-100 Å.

6. The method of claim 1, wherein the PFET workfunction metal layer is formed using atomic layer deposition (ALD).

7. The method of claim 1, further comprising forming a gate metal fill layer over the workfunction metal layer, thereby defining a gate stack.

8. A method of forming a complementary metal oxide semiconductor (CMOS) device, the method comprising:
forming an interfacial layer and a dielectric layer over a substrate; and
forming a p-type field effect transistor (PFET) workfunction metal layer over the dielectric layer in a PFET region, and forming an n-type field effect transistor (NFET) workfunction metal layer over the dielectric layer in an NFET region;
wherein the PFET workfunction metal layer comprises a lower titanium nitride (TiN) first layer and a second layer comprising one of a titanium-aluminum-carbide (TiAlC) layer and a tantalum-aluminum-carbide (TaAlC) layer formed on the lower TiN first layer.

9. The method of claim 8, wherein the lower TiN first layer is formed at thickness of about 2-8 angstroms (Å).

10. The method of claim 9, wherein the second layer is formed at thickness of about 12 Å or less.

11. The method of claim 10, further comprising forming an upper TiN layer third on the second layer, the upper TiN third layer being thicker than the lower TiN first layer.

12. The method of claim 11, wherein the upper TiN third layer is formed at a thickness of about 15-100 Å.

13. The method of claim 12, wherein the PFET workfunction metal layer is formed using atomic layer deposition (ALD).

14. The method of claim 13, further comprising forming a gate metal fill layer over the PFET and NFET workfunction metal layers, thereby defining a gate stack.

15. The method of claim 13, further comprising:
initially forming the PFET workfunction metal layer in both the PFET region and the NFET region;
removing the PFET workfunction metal layer from the NFET region; and
forming the NFET workfunction metal layer over the dielectric layer in the NFET region, and over the PFET workfunction metal layer in the PFET region.

16. The method of claim 13, further comprising:
initially forming the NFET workfunction metal layer in both the NFET region and the PFET region;
removing the NFET workfunction metal layer from the PFET region; and
forming the PFET workfunction metal layer over the dielectric layer in the PFET region, and over the NFET workfunction metal layer in the NFET region.

17. A transistor device, comprising:
an interfacial layer and a dielectric layer formed over a portion of a substrate; and
a p-type field effect transistor (PFET) workfunction metal layer formed over the dielectric layer, the workfunction metal layer comprising a lower titanium nitride (TiN) first layer and a second layer comprising one of titanium-aluminum-carbide (TiAlC) and tantalum-aluminum-carbide (TaAlC) formed on the lower TiN first layer.

18. The device of claim 17, wherein the lower TiN first layer is formed at thickness of about 2-8 angstroms (Å).

19. The device of claim 18, wherein the second layer is formed at thickness of about 12 Å or less.

20. The device of claim 19, further comprising an upper TiN third layer formed on the second layer, the upper TiN third layer formed at a thickness of about 15-100 Å.
